(19) United States
(12) Patent Application Publication
(10) Pub. No.: US 2016/0168708 A1
(43) Pub. Date: Jun. 16, 2016

(54) COMBINED HEAT TREAT AND THIN FILM COATING PROCESS

(71) Applicant: CATERPILLAR INC., Peoria, IL (US)

(72) Inventors: Steven TAYLOR, Germantown Hills, IL (US); Tianjun LIU, Edwards, IL (US); Scott JOHNSTON, East Peoria, IL (US)

(73) Assignee: CATERPILLAR INC., Peoria, IL (US)

(21) Appl. No.: 14/566,163

(22) Filed: Dec. 10, 2014

(51) Int. Cl. C23C 16/46; H01J 37/32; C23C 16/06; C23C 16/50; C23C 16/52

(52) U.S. Cl. CPC C23C 16/466; C23C 16/50; C23C 16/52; C23C 16/06; H01J 37/32522; H01J 37/32449; H01J 2237/3321

(57) ABSTRACT

A method of manufacturing a component includes providing a component machined or forged from an air-hardenable steel, and placing the component in a chemical vapor deposition (CVD) processing chamber. The method may include controlling the pressure within the processing chamber to a pressure that is below atmospheric pressure, inducting feedstock gases into the processing chamber, and increasing the temperature inside the processing chamber to a coating temperature at which one or more volatile precursors from the feedstock gases react on the surface of the component to produce a thin film coating. The temperature in the processing chamber may be maintained at the coating temperature for a period of time that includes at least one of a period of time before, during, and after the thin film coating is produced in order to austenitize the material of the component. After coating and austenitization of the component, the component may be cooled in a gaseous environment at a cooling rate sufficient to form one of a substantially fully martensitic or martensitic and lower-bainitic microstructure to a depth that is approximately 1% to 100% of a total thickness of the component.

### TECHNICAL FIELD

The present disclosure relates generally to a thin film coating process and, more particularly, to a combined heat treat and thin film coating process.

### BACKGROUND

Drivetrain and undercarriage components such as shafts, couplings, gears, cams, sprockets, and the pins and bushings used to hold together track linkages are frequently subjected to high pressures, torque loads, impact loading, and wear from abrasion. Undercarriage maintenance costs often constitute more than one quarter of the total costs associated with operating the earth-working machines. In order to facilitate relative rotation between parts of the undercarriage such as the pins and bushings in the track cartridges, and reduce wear from abrasion, the outer diameter surfaces of the pins and/or inner diameter surfaces of the bores through the bushings may be coated with a thin film coating to reduce friction. Before coating, the parts may be manufactured by machining and/or forging to a desired configuration, followed by heat treatment processes to obtain a desired microstructure having good toughness and wear characteristics.

Thin film coatings applied using methods such as chemical vapor deposition (CVD) may include materials possessing low friction, high wear or abrasion resistance, high scuffing resistance, and high galling resistance compared to steel. Galling failure is known to occur during the sliding contact between the pins and bushings in undercarriage track joint assemblies, particularly under high load applications. High load applications, such as incurred on larger, heavy-duty machinery, have typically mitigated the risk of galling through the use of sleeve bearings positioned around the outer diameter surface of the pins between the pins and the bushings. The use of sleeve bearings adds additional cost and design complexity. The hard thin film coating applied, for example, over the outer diameter surface of a pin in a track assembly may eliminate the need for a sleeve bearing between the pin and the bushing in high load applications, such as on large earth-moving tractors and bulldozers.

Thin film coatings may be formed on a component, for example, by a chemical vapor deposition (CVD) process. In a CVD process a processing chamber for storing base materials is evacuated, and then a feedstock gas including one or more volatile precursors, hydrogen gas, argon gas, and hydrocarbons such as methane is continuously inducted in the processing chamber while the pressure in the processing chamber is maintained at a prescribed pressure. In the case of plasma-assisted chemical vapor deposition (PACVD), a voltage may be applied to the base material and/or to walls of the processing chamber in order to produce plasma in the processing chamber. Accordingly, ions and radicals are generated from the feedstock gas, and chemical reactions are initiated in order to deposit a thin film coating on the surface of the base material. The temperatures at which the CVD process is performed typically range between approximately 800 degrees C. and 1100 degrees C. Generation of thin film coatings through processes such as CVD may add significantly to the number of processing steps and the costs of manufacturing and heat treating a component.

An exemplary method of heat treating a steel component in order to impart desirable toughness and hardness characteristics is disclosed in U.S. Pat. No. 8,404,061 to Braun et al. (“the '061 patent”), issued Mar. 26, 2013. As disclosed in the '061 patent, heat treatment steps may include heating a hard-rolled or cold-rolled steel blank of air-hardenable steel to a temperature of 800 degrees C. to 1050 degrees C., partially cooling the component while in a forming tool, and following this partial cooling with further air cooling at a cooling rate less than the cooling rate in the forming tool. While the processes disclosed in the '061 patent may result in a component that has some desirable characteristics, these heat treatment processes require complex controls and are additional to any processing steps associated with providing a thin film coating on the component to further improve wear characteristics of the component.

Steel parts produced and coated in accordance with the processes of the present disclosure solve one or more of the problems set forth above and/or other problems in the art.

### SUMMARY

In one aspect, the present disclosure is directed to a method of manufacturing a component. The method may include providing a component machined or forged from an air-hardenable steel. The component may be placed in a CVD processing chamber and subjected to a pressure that is below atmospheric pressure. The method may further include inducting feedstock gases into the processing chamber and increasing the temperature inside the processing chamber to a coating temperature at which one or more volatile precursors from the feedstock gases react on the surface of the component to produce a thin film coating. The method may still further include maintaining the temperature in the processing chamber at the coating temperature for a period of time that includes at least one of a period of time before, during, and after the thin film coating is produced in order to austenitize the material of the component. After austenitization, the coated component may be cooled in a gaseous environment at a cooling rate sufficient to form one of a substantially fully martensitic or martensitic and lower-bainitic microstructure to a depth that is approximately 1% to 100% of a total thickness of the component.

In a further aspect, the present disclosure is directed to a system for performing combined heat treatment and thin film coating of a component machined or forged from an air-hardenable steel. The system may include a chemical vapor deposition (CVD) processing chamber and a controller configured to control heat treatment and coating parameters in the CVD processing chamber. The controller may be configured to control the pressure within the processing chamber to a pressure that is below atmospheric pressure, control the induction of feedstock gases into the processing chamber, and increase the temperature inside the processing chamber to a coating temperature at which one or more volatile precursors from the feedstock gases react on the surface of the component to produce a thin film coating. The controller may also be configured to maintain the temperature in the processing chamber at the coating temperature for a period of time that includes at least one of a period of time before, during, and after the thin film coating is produced in order to austenitize the material of the component. The controller may be still further configured to cool the component after austenitization in a gaseous environment at a cooling rate sufficient to form one of a substantially fully martensitic or martensitic and lower-bainitic microstructure to a depth that is approximately 1% to 100% of a total thickness of the component.

In yet another aspect, the present disclosure is directed to a method of coating and heat treating a component. The method may include placing a component machined or forged from an air-hardenable steel into a chemical vapor deposition (CVD) processing chamber, controlling the pressure within the processing chamber to a pressure that is below atmospheric pressure, inducting feedstock gases into the processing chamber, applying an electrical voltage to at least one of the component and the processing chamber, and increasing the temperature inside the processing chamber to a coating temperature at which one or more volatile precursors from the feedstock gases react on the surface of the component to produce a thin film coating. The method may further include maintaining the temperature in the processing chamber at the coating temperature for a period of time that includes at least one of a period of time before, during, and after the thin film coating is produced such that the material of the component is austenitized to a depth that is between 1% and 100% of the entire thickness of the component. The method may still further include cooling the coated component after austenitization in a gaseous environment at a cooling rate sufficient to form one of a substantially fully martensitic or martensitic and lower-bainitic microstructure to the austenitized depth.

### BRIEF DESCRIPTION OF THE DRAWINGS

FIG. 1 is a schematic diagram of an exemplary chemical vapor deposition (CVD) process used in manufacturing a component;

FIG. 2 shows an example of the types of components that may be manufactured according to the processes of the disclosure;

FIG. 3 is a continuous cooling transformation (CCT) diagram showing the temperatures and cooling rates used to produce the desired microstructure of a component; and

FIG. 4 is a flowchart depicting an exemplary disclosed method that may be used to simultaneously heat treat and thin film coat a component.

### DETAILED DESCRIPTION

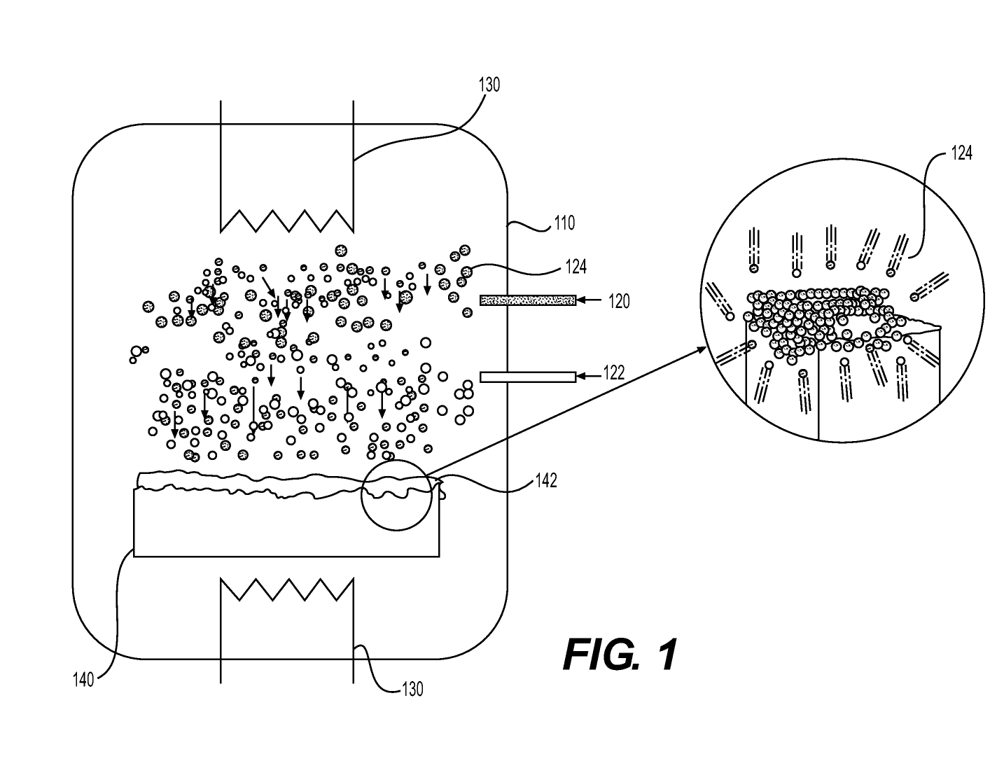

FIG. 1 shows an exemplary processing chamber 110 in which a chemical vapor deposition (CVD) coating process may be performed on a manufactured component 140. A process in accordance with various implementations of this disclosure may combine some process steps employed during the application of a thin film coating 142 to a component 140 using a CVD process in a processing chamber 110 such as the one illustrated in FIG. 1, and heat treatment of the component 140 to achieve a desired microstructure. As shown in FIG. 1, one or more heaters 130 may be provided in the processing chamber 110, and additional features such as pumps, valves, and electrical power sources (not shown) may also be associated with the processing chamber 110 in order to enable implementation of a CVD process in the chamber. Feedstock gases 120, 122 may be pumped into the chamber 110 at controlled flow rates in order to initiate a thin film coating process. One or more vacuum pumps (not shown) may also be provided for at least partially evacuating the chamber 110 to produce pressures less than atmospheric pressure in the chamber 110. The component 140 may be heated by the one or more heaters 130 to a coating temperature at which one or more volatile precursors 124 from the feedstock gases 120, 122 react on the surface of the component 140 to produce the thin film coating 142.

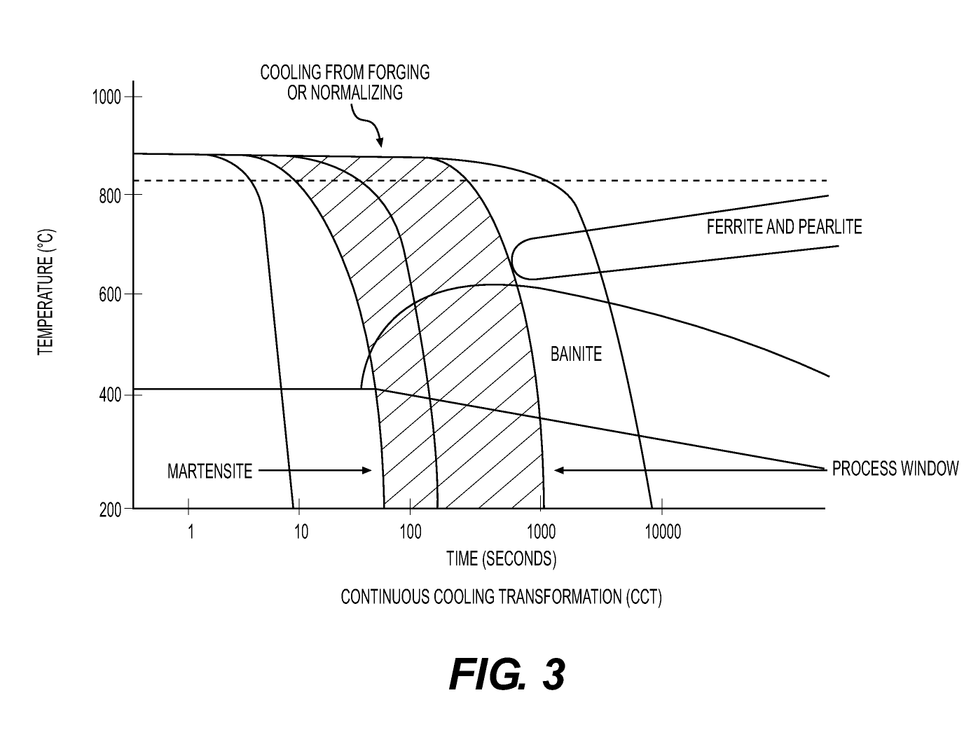

The disclosed process achieves savings in costs and time by taking advantage of the temperatures that are used during the CVD coating process to also heat treat the component 140. Various exemplary implementations of the disclosed process include performing the combined heat treatment and thin film coating to a component 140 manufactured from an “air-hardenable” steel. The term “air-hardenable” steel as used throughout this disclosure refers to types of steel and steel alloys that have sufficient hardenability to form a substantially fully martensitic or martensitic and lower-bainitic microstructure to a desired depth below the surface of a component after the component is allowed to cool at ambient temperatures following austenitization. Reference to “substantially fully martensitic” as used in this disclosure means a microstructure that is 70% or more martensite. Many air-hardenable steels are characterized by low distortion during heat treatment because of high chromium content. The presence of alloys in the air-hardenable steels also allows these types of steel to achieve desired hardness and toughness while avoiding the higher stresses that would result from faster quenching processes such as water quenching. A material with high hardenability, such as air-hardenable steel, is able to form a substantially fully martensitic and/or lower-bainitic microstructure after austenitization with a relatively slow cooling rate. Austenitization refers to heat treating the steel to a temperature at which it changes crystal structure from ferrite to austenite. This change in crystal structure is characterized by a phase change from a body-centered cubic (BCC) to face-centered cubic (FCC) configuration. As shown in the continuous cooling transformation (CCT) diagram of FIG. 3, an air-hardenable steel component may be retained at temperatures in the range from approximately 800 degrees C. to 850 degrees C. for a period of time during austenitization to allow the component to normalize. Normalization is a type of annealing process used to relieve stress in hardenable steel after cold working, such as machining or forging, and improve ductility and toughness properties.

The cooling after austenitization may be performed in various ways in order to achieve a desired rate of cooling. The air-hardenable steels referred to above are characterized by the ability to achieve a microstructure that is substantially fully martensite, a mixture of martensite and lower-bainite, or lower-bainite, as shown on the CCT graph of FIG. 3 after being cooled at ambient temperatures. The air-hardenable steels may include various percentages of alloying elements that allow for the transformation to substantially fully martensite and/or lower-bainite at ambient temperatures, without requiring fast quenching such as in water. Martensite is normally formed in carbon steels as a result of rapid cooling of austenite at such a high rate that carbon atoms do not have time to diffuse out of the crystal structure in large enough quantities to form cementite. The FCC configuration of austenite is then transformed into a distorted body-centered tetragonal structure with a high concentration of dislocations in the ferrite, which contribute to a high hardness. The presence of various alloying elements in the steel allows for the formation of martensite at slower cooling rates. Both martensite and lower-bainite have high concentrations of dislocation-rich ferrite, which contributes to these microstructures having high hardness. A fully martensitic microstructure would have a higher hardness than a substantially fully martensitic microstructure, which would have a higher hardness than a lower-bainitic microstructure.

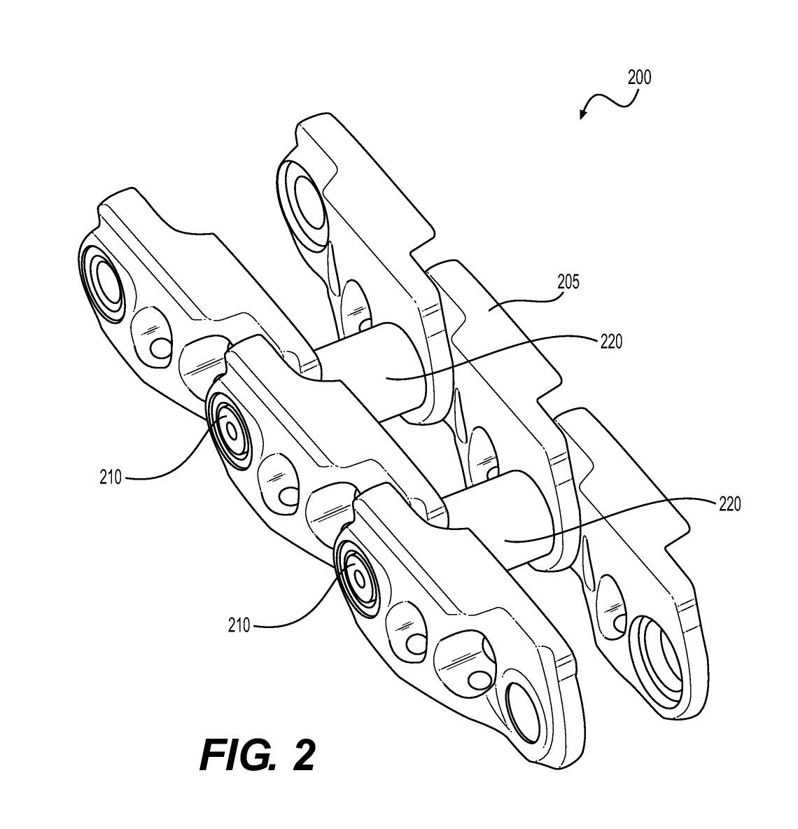

The temperatures that are used during the CVD process within the processing chamber 110 shown in FIG. 1 may fall within the same range of temperatures from approximately 800 degrees C. to 850 degrees C. required to austenitize components made from air-hardenable steel. Therefore, various implementations of this disclosure may take advantage of these similar temperature requirements to combine desired heat treatment and thin film coating of components that will be used in high wear applications, such as the pins and/or bushings of track linkages for track-type tractors. As shown in FIG. 2, a track linkage 200 for a track-type tractor may include links 205 held together by multiple pins 210 and bushings 220. Relative rotation between at least the pins 210 and bushings 220 as the track linkage 200 moves across drive sprockets (not shown) on the undercarriage of a track-type tractor results in wear on both the outer surfaces of the pins 210 and the inner surfaces of the bushings 220. Therefore, the pins 210 and the bushings 220 are examples of components that may benefit from the combined heat treatment and thin film coating processes of the present disclosure.

An advantage of combining the heating steps used during a CVD coating process with heat treatment of the component is the ability to use a significantly wider range of materials in the CVD coating process than would be the case when the heat treatment is performed before the coating. This is because there are a limited number of materials that can be austenitized and then quenched to form a substantially fully martensitic and/or lower-bainitic microstructure, and then subjected to the temperatures required during the CVD coating process without losing the advantageous characteristics imparted during the previous heat treatment. Elimination of the previous heat treatment steps, and achieving the desired microstructure as a result of heating and cooling steps performed during the coating process enables the use of many more, less expensive, and readily available materials.

As shown in FIG. 1, a chemical vapor deposition (CVD) process typically includes heating the component 140 with the heaters 130 during the induction of the various feedstock gases 120, 122 into the processing chamber 110. The temperatures that are required for the CVD coating process may also be maintained for a longer period of time than necessary to actually apply a thin film coating. While the coating process may only require that a very thin layer at the top surface of the component be heated, a desired heat treatment of the component 140 may include heating a substantial thickness of the component. In various exemplary implementations, heat treatment may be performed in order to change the microstructure through 1% to 100% of the total thickness of the component, depending on potential applications of the finished component. Heat treatment of a greater thickness of the component may require maintaining the component at elevated temperatures for longer than needed to complete thin film coating. The length of time during which the component is heated may be based upon the percentage of total thickness of the component through which changes in the microstructure are desired. Therefore, the temperature in the processing chamber 110 may be maintained at the coating temperature for a period of time that includes at least one of a period of time before, during, and after producing the thin film coating in order to also austenitize a substantial thickness of the component 140.

In one non-limiting example, a component 140 may be placed in the processing chamber 110 of FIG. 1 and then heated to austenitization temperatures of approximately 800 degrees C. to 850 degrees C. for a period of time before commencing the coating process. The component may be maintained at the elevated austenitization temperatures in order to achieve normalization throughout an entire thickness, or substantially all of the thickness of the component. This lengthened heating process may be performed even though the coating process by itself may only require heating for long enough to bring a relatively small percentage of the thickness of the component below the surface up to temperature. In one exemplary implementation, the heaters 130 may be operated for a period of time after the component 140 is placed into the chamber 110, and before the feedstock gases 120, 122 are introduced into the chamber 110 to initiate deposition of a thin film coating on the component 140. Vacuum pumps (not shown) may also be operated in order to at least partially evacuate the chamber 110 while the component 140 is being heated, and before the introduction of the feedstock gases. Significant cost savings may be achieved if an air-hardenable steel is used in manufacturing the component, such that additional heating, quenching, reheating, and tempering steps are not required to achieve a desired microstructure before the CVD thin film coating process. Capital investments for heat treatment capacity, and maintenance costs on the furnaces and other equipment may be reduced.

In order to provide a lower deposition temperature than may normally be required during a CVD thin film coating process, a process referred to as plasma-activated CVD (PACVD) may be used. In a plasma of a low pressure glow discharge within the processing chamber, the gas mixture may be composed of neutral particles, molecules, dissociated molecules, ions and electrons. Due to the lack of an equilibrium state during the low pressure discharge, the temperature of the electrons may be several thousand degrees higher than that of the heavy particles, i.e., ions and neutral particles. This may cause activation of the chemical reaction(s) of the CVD thin film coating process at temperatures below the 1,000 degrees C. that may otherwise be required in a CVD coating process. The lowered range of temperatures at which the thin film coating may be performed in a PACVD process may also be advantageous for heat treatment of the material in accordance with the principals of this disclosure. As one example, heating of some air-hardenable steels to 1,000 degrees C. may have the undesired effect of causing too much austenite to be retained during cooling. The retention of austenite may prevent the heat treatment from resulting in the desired substantially fully martensitic and/or lower-bainitic microstructure to a desired depth. A low pressure plasma may be generated in the processing chamber 110, for example, by application of a DC voltage or a high frequency AC voltage to at least one of the component 140 and the inner walls of the chamber 110, at pressures ranging from 10 to 10,000 Pascal. A low pressure discharge may be produced within the processing chamber by connecting the component 140 to the cathode of a direct current source, and connecting the walls of the CVD processing chamber 110, at least a portion of which are electrically conductive, to the anode of the direct current source.

After heating the component in the processing chamber to achieve austenitization through a desired thickness of the component, and effecting deposition of a thin film coating on the component, the coated component may be held in a gaseous environment within the processing chamber. The pressure within the processing chamber may be at or below atmospheric pressure, the feedstock gases may be purged from the chamber, and a flow of ambient temperature gases may be provided through the chamber. In some applications pressures below atmospheric pressure may allow for lower coating temperatures than would otherwise be required. Therefore, control of the pressure in the processing chamber during the deposition of a thin film coating may also allow for adjustment of the temperatures required during the coating process such that those temperatures also coincide with the desired austenitization temperatures for the component. In alternative implementations, the coated component may be moved into a separate chamber or environment for the cooling process. The gaseous environment within the CVD processing chamber after coating is complete may include gases such as hydrogen and nitrogen that are provided at a low flow rate and ambient temperatures in order to cool the component after coating and austenitization.

The heat treatment performed within the processing chamber simultaneously with the CVD coating process may be designed to achieve a substantially fully martensitic and/or lower-bainitic microstructure in the component to any desired depth. A desired depth from the surface of the component may be a depth of approximately 1% to 100% of the total thickness of the component, depending on the application and intended use of the component. In some exemplary implementations, the air-hardenable steel may be heated to a temperature range from approximately 800 degrees C. to approximately 850 degrees C. and held at that elevated level for approximately 1 hour to 3 hours under a slight vacuum in order to form an austenite microstructure to the desired depth. Cooling at ambient temperatures following the austenitization may be performed by allowing the component to sit in the same chamber in which the coating was performed while purging the chamber with gases as mentioned above. The chamber may be purged with ambient temperature gases surrounding the part that help to prevent oxidation during the cooling, and to achieve a desired cooling rate. In alternative implementations the thin film coated component may be moved to a separate container or cooling environment for at least a portion of the cooling process.

In various alternative implementations, the cooling after the thin film coating may be conducted by atmospheric cooling or forced air cooling using a blower. The steel may be cooled rapidly down to about the eutectoid transformation temperature, and then cooled slowly over a range from about 900 to 500° C. In still further alternative implementations, the steel may be cooled quickly to about 500 to 300° C. after thin film coating, and may be kept at an equilibrium temperature somewhere in the range from about 500 to 300° C. to promote lower-bainitic transformation rather than substantially fully martensitic transformation.

The cooling rate after austenitization of the material of the component may be determined by reference to a CCT diagram, such as that shown in FIG. 3. A CCT diagram may show the range for cooling rates passing through the lower-bainitic and martensitic transformation regions for the material from which the component is manufactured. The data shown on the CCT diagram may also be provided in the form of tables, maps, equations, or other compilations of the data. A controller may be provided for controlling the temperatures within the CVD processing chamber in accordance with the determined rates of heating and cooling. The CCT diagram, or data from the CCT diagram may have been previously determined from historical and/or empirical data, prepared, stored in a database, or otherwise made available for control of the heat treatment process. A system in accordance with various implementations of this disclosure may acquire and process information stored in data files on at least one storage medium, where the information is related to temperatures, heating and cooling rates, as well as other thin film coating and heat treatment control parameters. The controller may be configured to control the operation of pumps, valves, and power sources in order to control the pressure in the processing chamber, heating elements, flow rates of gases, fans or other means of circulating cooling air or gases to achieve a desired cooling rate, and other control parameters. One of ordinary skill in the art will recognize that one or more controllers configured to control the various operating parameters of the CVD thin film coating and heat treatment process in accordance with various implementations of this disclosure may be included in any computing platform or device. Data files including information such as temperatures and cooling rates from CCT diagrams for various materials may be stored on any combination of one or more computer readable storage medium(s). The one or more controllers may be configured to retrieve data from the one or more computer readable storage mediums and control the various operating parameters of the CVD thin film coating and heat treatment process based on the retrieved data.

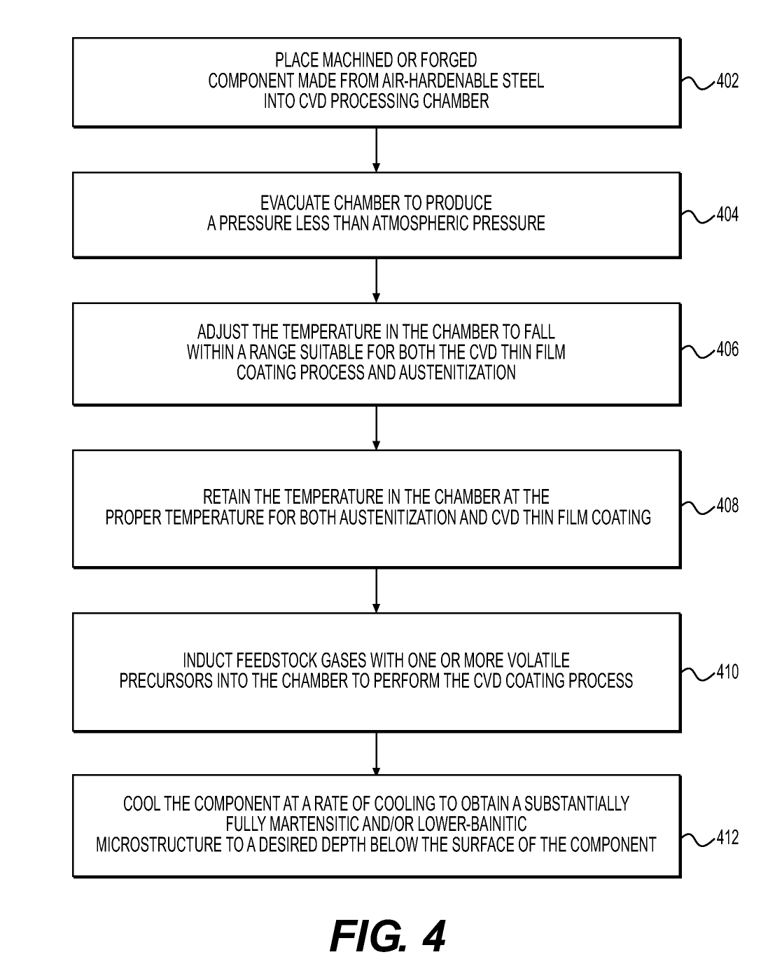

FIG. 4 illustrates an exemplary method that may be used to produce a thin film coated, substantially fully martensitic and/or lower-bainitic microalloyed steel component in accordance with various implementations of this disclosure. FIG. 4 will be discussed in more detail in the following section to further illustrate the disclosed concepts.

### INDUSTRIAL APPLICABILITY

The method of manufacturing a component in accordance with various implementations of the present disclosure may reduce costs and simplify production by eliminating the need for heat treatment steps separate from the heating that is performed during a CVD thin film coating process.

As shown in FIG. 4, at step 402, an air-hardenable, microalloyed steel may be forged or machined into the desired shape for a component. The component may then be placed in the processing chamber for performing CVD thin film coating. Exemplary types of parts being manufactured in accordance with various implementations of this disclosure may include pins, bushings, and other components used in the track linkages for heavy, earth-moving machinery, and any component that benefits from the improved toughness and wear characteristics associated with a thin film coating and a substantially fully martensitic and/or lower-bainitic microstructure.

At step 404, the processing chamber may be evacuated in order to generate a pressure less than atmospheric pressure. In various non-limiting implementations, the pressure in the processing chamber may be in the range from approximately 10 Pascals to 10,000 Pascals. As discussed above, the presence of at least a partial vacuum in the processing chamber may allow the CVD thin film coating process to be performed at lower temperatures than would otherwise be required. Control of the pressure in the processing chamber therefore provides an additional parameter that can be adjusted in order to enable combined heat treatment and thin film coating to occur simultaneously.

At step 406, the temperature in the chamber may be adjusted to fall within a range that is suitable for performing the CVD thin film coating process, and that coincides with the austenitization temperature for the material of the component. As discussed above, one exemplary implementation may include heating the component to a temperature within a range from approximately 800 degrees C. to 850 degrees C.

At step 408, the temperature in the chamber may be retained in the proper range for long enough to both produce a desired thin film coating on the component, and to austenitize and normalize the material of the component to relieve cold working stresses. The time period during which the component is heated to proper temperatures for both austenitization and CVD thin film coating may include at least one of a period of time before, during, and after the thin film coating is produced in order to austenitize the material of the component, and normalize the material to a desired depth.

At step 410, induction of feedstock gases with one or more volatile precursors into the chamber is performed during the CVD coating process. In the case of PACVD, an electrical voltage may also be applied to the component in order to allow the coating process to occur at lower temperatures than would otherwise be required.

At step 412, after the coating is complete, and the component has been retained at austenitization temperature for the required length of time, the component is cooled by the introduction of ambient temperature gases into the chamber. The rate of cooling is controlled in order to obtain a substantially fully martensitic and/or lower-bainitic microstructure to a desired depth below the surface of the component.

It will be apparent to those skilled in the art that various modifications and variations can be made to the disclosed method and system for combining heat treatment and thin film coating of an air-hardenable steel component without departing from the scope of the disclosure. Alternative implementations will be apparent to those skilled in the art from consideration of the specification and practice disclosed herein. It is intended that the specification and examples be considered as exemplary only, with a true scope of the disclosure being indicated by the following claims and their equivalents.

1. A method of manufacturing a component, comprising:
providing a component machined or forged from an air-hardenable steel;
placing the component in a chemical vapor deposition (CVD) processing chamber;
controlling the pressure within the processing chamber to a pressure that is below atmospheric pressure;
inducting feedstock gases into the processing chamber;
increasing the temperature inside the processing chamber to a coating temperature at which one or more volatile precursors from the feedstock gases react on the surface of the component to produce a thin film coating;
maintaining the temperature in the processing chamber at the coating temperature for a period of time that includes at least one of a period of time before, during, and after the thin film coating is produced in order to austenitize the material of the component; and
after austenitization, cooling the coated component in a gaseous environment within the processing chamber at a cooling rate sufficient to form one of a substantially fully martensitic or martensitic and lower-bainitic microstructure to a depth that is approximately 1% to 100% of a total thickness of the component, wherein cooling within the processing chamber includes varying the cooling rate of the component during different ranges of temperature of the component.

2. The method of claim 1, wherein the temperature inside the processing chamber is increased to a range from 800 degrees C. to 850 degrees C.

3. The method of claim 1, further including applying an electrical voltage to the component in the processing chamber to perform a plasma assisted chemical vapor deposition (PACVD) process.

4. The method of claim 1, wherein the pressure within the chamber is maintained in the range from 10 to 10,000 Pascals.

5. The method of claim 1, wherein the coating temperature in the chamber is maintained for a period of time from 1 hour to 3 hours in length.

6. The method of claim 1, wherein the period of time to austenitize the material of the component is longer than the period of time required for producing the thin film coating on the component.

7. (canceled)

8. (canceled)

9. The method of claim 1, wherein the cooling of the component after austenitization is performed at a rate determined from a continuous cooling transformation (CCT) diagram characteristic of the material from which the component is manufactured.

10. A system for performing combined heat treatment and thin film coating of a component machined or forged from an air-hardenable steel, the system comprising:
a chemical vapor deposition (CVD) processing chamber; and
a controller configured to control heat treatment and coating parameters in the CVD processing chamber, the controller configured to:
control the pressure within the processing chamber to a pressure that is below atmospheric pressure;
control an induction of feedstock gases into the processing chamber;
increase the temperature inside the processing chamber to a coating temperature at which one or more volatile precursors from the feedstock gases react on the surface of the component to produce a thin film coating;
maintain the temperature in the processing chamber at the coating temperature for a period of time that includes at least one of a period of time before, during, and after the thin film coating is produced in order to austenitize the material of the component; and
cool the component after austenitization in a gaseous environment at a cooling rate sufficient to form one of a substantially fully martensitic or martensitic and lower-bainitic microstructure to a depth that is approximately 1% to 100% of a total thickness of the component.

11. The system of claim 10, wherein the controller is configured to control the temperature inside the processing chamber to a range from 800 degrees C. to 850 degrees C.

12. The system of claim 10, wherein the controller is further configured to apply an electrical voltage to the component in the processing chamber to perform a plasma assisted chemical vapor deposition (PACVD) process.

13. The system of claim 10, wherein the controller is configured to control the pressure within the chamber to a range from 10 to 10,000 Pascals.

14. The system of claim 10, wherein the controller is configured to maintain the coating temperature in the chamber for a period of time from 1 hour to 3 hours in length.

15. The system of claim 10, wherein the controller is configured to maintain the coating temperature for a period of time to austenitize the material of the component that is longer than a period of time required for producing the thin film coating on the component.

16. The system of claim 10, wherein the controller is configured to control cooling of the component after austenitization by controlling a gaseous environment within the processing chamber.

17. The system of claim 16, wherein the controller is further configured to control cooling of the component after austenitization by varying the cooling rate of the component during different ranges of temperature of the component.

18. The system of claim 10, wherein the controller is configured to determine the cooling rate of the component after austenitization from a continuous cooling transformation (CCT) diagram characteristic of the material from which the component is manufactured.

19. A method of coating and heat treating a component, comprising:
placing a component machined or forged from an air-hardenable steel into a chemical vapor deposition (CVD) processing chamber;
controlling the pressure within the processing chamber to a pressure that is below atmospheric pressure;
inducting feedstock gases into the processing chamber;
applying an electrical voltage to the component;
increasing the temperature inside the processing chamber to a coating temperature at which one or more volatile precursors from the feedstock gases react on the surface of the component to produce a thin film coating;
maintaining the temperature in the processing chamber at the coating temperature for a period of time that includes at least one of a period of time before, during, and after the thin film coating is produced such that the material of the component is austenitized to a depth that is between 1% and 100% of an entire thickness of the component; and
after austenitization, cooling the coated component in a gaseous environment within the processing chamber at a cooling rate sufficient to form one of a substantially fully martensitic or martensitic and lower-bainitic microstructure to the austenitized depth, wherein cooling within the processing chamber includes varying the cooling rate of the component during different ranges of temperature of the component.

20. The method of claim 19, wherein the temperature inside the processing chamber is increased to a range from 800 degrees C. to 850 degrees C.
